(19) United States
(12) Patent Application Publication
(10) Pub. No.: US 2022/0223683 A1
(43) Pub. Date: Jul. 14, 2022

(54) INTEGRATED GUARD STRUCTURE FOR CONTROLLING CONDUCTIVITY MODULATION IN DIODES

(71) Applicant: Texas Instruments Incorporated, Dallas, TX (US)

(72) Inventor: Aravind Chennimalai Appaswamy, Plano, TX (US)

(21) Appl. No.: 17/536,388

(22) Filed: Nov. 29, 2021

Related U.S. Application Data
(60) Provisional application No. 63/137,627, filed on Jan. 14, 2021.

(51) Int. Cl. H01L 29/06; H01L 29/861; H01L 29/66; H01L 21/761

(52) U.S. Cl. CPC H01L 29/0619; H01L 21/761; H01L 29/66128; H01L 29/8611

(57) ABSTRACT

A microelectronic device includes an integrated guard structure diode on the substrate. The integrated guard structure diode includes a first terminal of the diode, a second terminal of the diode, and a guard structure. The guard structure is between the first terminal of the diode and the second terminal of the diode. The first terminal of the diode and guard structure are electrically connected to each other. An optional switching element may provide selective electrical connection between the first terminal of the diode and the guard structure. Adding a guard structure electrically connected first terminal of the diode, with the guard structure between the first terminal of the diode and the second terminal of the diode provides higher break down voltage than a diode without a guard structure.

### CROSS-REFERENCE TO RELATED APPLICATIONS

This application is related to U.S. Provisional Patent Application No. 63/137,327 (Texas Instruments Docket No. T91896US01), filed on Jan. 14, 2019, and hereby incorporated herein by reference in its entirety.

### FIELD

This disclosure relates to the field of microelectronic devices. More particularly, but not exclusively, this disclosure relates to integrated guard structures in diodes.

### BACKGROUND

Diodes have been formed in microelectronic devices as part of ElectroStatic Discharge (ESD) and overvoltage protection circuits. Some methods of forming diodes may need protection under electrostatic discharge conditions and overvoltage conditions to maintain safe operating area of the microelectronic device. Improvements integrating diodes into microelectronic devices are needed.

### SUMMARY

The present disclosure introduces a microelectronic device including an integrated guard structure diode. The diode has a first terminal of the diode herein referred to as the first terminal and a second terminal of the diode herein referred to as the second terminal with both being internal to the microelectronic device. The first terminal may be a cathode and the second terminal may be an anode or vis versa. The first terminal is of a first conductivity type, the second terminal is of a second conductivity type, and a guard structure is of the second conductivity type laterally separated from the second terminal. The guard structure has a conductive connection between the guard structure and the first terminal of the diode. The guard structure may contain a switching element. The guard structure is between the first terminal and the second terminal. The guard structure of the integrated guard structure diode provides a controllable saturating element which offers low impedance during low current conditions and high impedance during high injection which is advantageous to optimize circuit protection during ESD and overvoltage conditions.

### BRIEF DESCRIPTION OF THE VIEWS OF THE DRAWINGS

FIG. 1 shows cross sectional view of an example microelectronic device with an integrated guard structure diode.

FIG. 2 shows a cross sectional view of an example microelectronic device with an integrated guard structure diode.

FIG. 3 presents a flowchart of an example method of forming the microelectronic device of FIG. 1.

FIG. 4 is a top down view of an example microelectronic device including an integrated guard structure diode.

FIG. 5 is a top down view of a microelectronic device with an integrated guard structure diode.

FIG. 6 is a top down view of a microelectronic device with an integrated guard structure diode.

FIG. 7 is a graph comparing the leakage current versus reverse bias voltage of a diode with a guard ring structure and a diode without a guard ring structure.

### DETAILED DESCRIPTION

The present disclosure is described with reference to the attached figures. The figures are not drawn to scale and they are provided merely to illustrate the disclosure. Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events. Furthermore, not all illustrated acts or events are required to implement a methodology in accordance with the present disclosure.

In addition, although some of the embodiments illustrated herein are shown in two dimensional views with various regions having depth and width, it should be clearly understood that these regions are illustrations of only a portion of a device that is actually a three dimensional structure. Accordingly, these regions will have three dimensions, including length, width, and depth, when fabricated on an actual device. Moreover, while the present invention is illustrated by embodiments directed to active devices, it is not intended that these illustrations be a limitation on the scope or applicability of the present invention. It is not intended that the active devices of the present invention be limited to the physical structures illustrated. These structures are included to demonstrate the utility and application of the present invention to presently preferred embodiments.

It is noted that terms such as top, bottom, front, back, over, above, under, and below may be used in this disclosure. These terms should not be construed as limiting the position or orientation of a structure or element, but should be used to provide spatial relationship between structures or elements. Similarly, words such as “inward” and “outward” would refer to directions toward and away from, respectively, the geometric center of a device or area and designated parts thereof.

For the purposes of this disclosure, the term “lateral” refers to a direction parallel to a plane of the instant top surface of the microelectronic device the term “vertical” is understood to refer to a direction perpendicular to the plane of the instant top surface of the microelectronic device.

For the purposes of this disclosure, the term “conductive” is understood to mean “electrically conductive”.

For the purposes of this disclosure, the term “characteristic of an ESD event” refers to overvoltage transients encompassing any overvoltage transients prescribed by the Human Body Model, the Charged Device Model, the Machine Model, or the IEC 61000-4-2 Immunity Standard. The Human Body Model may be implemented by discharging a charged 100 picofarad (pF) capacitor through a 1.5 kilo ohm (kohm) resistor in series with a device under test (DUT), exhibiting a rise time less than 10 nanoseconds. The Charged Device Model may be implemented by discharging a charged DUT through a parasitic inductance in series with a 1 ohm resistor, exhibiting a rise time of less than 1 nanosecond. The Machine Model may be implemented by discharging a charged 200 pF capacitor through a 0.5 microhenry (uH) inductor in series with a DUT, exhibiting a rise time of less than 10 nanoseconds. The IEC 6100 4 2 Immunity Standard specifies a rise time of 0.6 nanoseconds to 1 nanosecond. The term “characteristic of an ESD event” excludes, that is does not encompass, voltage surge events, with a rise times longer than 500 nanoseconds. Thus, in some cases, overvoltage transients may exhibit characteristics of an ESD event, that is high voltages, over 100 volts, with short durations, typically less than 100 nanoseconds, and energies less than 1 millijoule. In other cases, overvoltage transients may exhibit characteristics of a voltage surge event, that is, voltages that are several volts above the maximum safe operating range of voltage sensitive circuits, with high current capacities greater than an ampere, rise times longer than 500 nanoseconds, durations of greater than 1 millisecond, an energies greater than 100 millijoules.

For the purposes of this disclosure, rise time is defined as a time duration for a transient to increase in potential from 20 percent of a peak potential of the transient to 80 percent of the peak potential. For the purposes of this disclosure, the term “high impedance state” refers to a circuit node having an impedance of at least 100 kohms to any DC line such as a power line or ground line.

A microelectronic device is formed in and on a substrate having a semiconductor material. The microelectronic device includes an integrated guard structure diode in the substrate herein referred to as the diode. The semiconductor and a first terminal of the diode have a first conductivity type. A second terminal of the diode and a guard structure of the diode have a second conductivity type. The guard structure in the semiconductor material is between the first terminal and the second terminal of the diode.

The guard structure is laterally separated from the second terminal of the diode. The lateral separation may be achieved by means of preventing silicide formation at the top surface of the substrate. A field oxide, a silicide blocking layer or polysilicon with dielectric sidewalls are several possible methods to laterally separate the second terminal of the diode from the guard structure. The dielectric sidewalls may be one of silicon dioxide, silicon oxynitride, and silicon nitride.

The guard structure has a conductive connection to the first terminal of the diode. The conductive connection may be through silicide on the surface of the silicon or through the interconnect system. The conductive connection between the first terminal of the diode and the guard structure allows the guard structure to provide a saturating element in the diode which drains away minority charge carriers which minimizes conductivity modulation. The guard structure allows the integrated guard structure diode to act as a highly saturating resistor at high injection.

The conductive connection between the first terminal of the diode and the guard structure may contain a switching element. When a guard structure integrated diode is used in parallel with a traditional ESD circuit, the switching element can be open at low impedance during ESD events when the microelectronic device is off. When the microelectronic device is on, the switching element can be closed and the guard structure integrated diode provides high impedance during overvoltage events and acts as a current limiter.

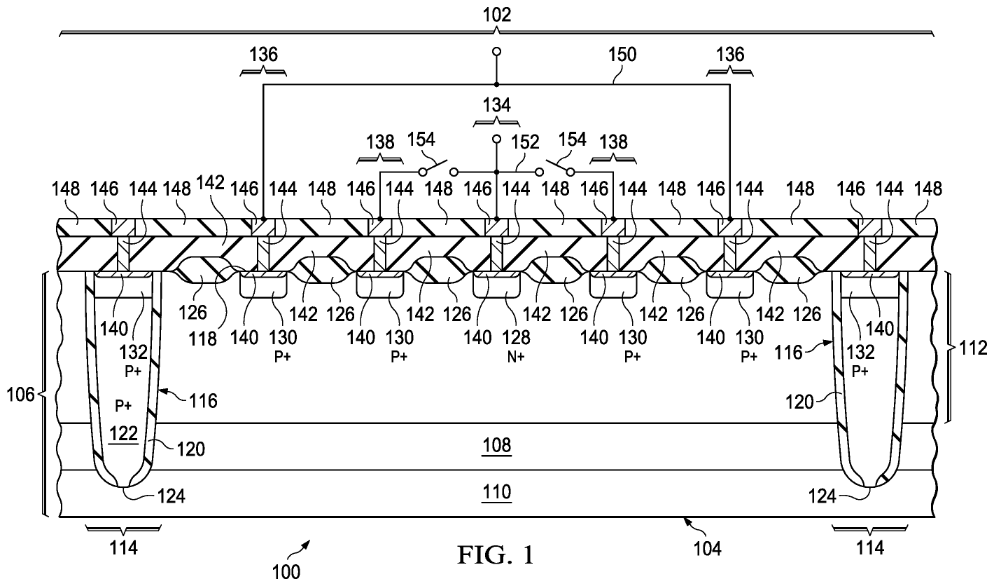

FIG. 1 shows cross sectional view of a microelectronic device 100 including a diode 102. The microelectronic device 100 may be manifested as a discrete semiconductor device, an integrated circuit, a micro-electrical mechanical system (MEMS) device, an electro-optical device, or a microfluidic device, by way of example. The substrate 104 may be, for example, part of a bulk semiconductor wafer, part of a semiconductor wafer with an epitaxial layer, part of a silicon-on-insulator (SOI) wafer, or other structure suitable for forming the microelectronic device 100.

The substrate 104 may include a n-type buried layer (NBL) 108 on a base wafer 110. The base wafer 110 may be p-type with a dopant concentration of 1×10¹⁷ atoms/cm³ to 1×10¹⁸ atoms/cm³, for example. Alternatively, the base wafer 110 may be lightly doped, with an average dopant concentration below 1×10¹⁶. The NBL 108 may be 2 microns to 10 microns thick, by way of example, and may have a dopant concentration of 1×10¹⁷ atoms/cm³ to 1×10¹⁹ atoms/cm³. The base wafer 110 may include an epitaxial layer 112 of silicon on the NBL 108. The epitaxial layer 112 is part of the silicon 106, and may be 2 microns to 12 microns thick, for example. The epitaxial layer 112 may be of the first connectivity type (n-type in this example), with a dopant concentration of 1×10¹⁵ atoms/cm³ to 1×10¹⁶ atoms/cm³, by way of example.

The silicon 106 may include a ring of integrated deep trench 114 around the diode 102 to provide isolation from other components of the microelectronic device 100. One example integrated deep trench 114 includes a deep trench 116 which extends from the top surface 118 into the base wafer 110. The deep trench 116 includes a deep trench sidewall dielectric layer 120 on the surface of the deep trench. The deep trench sidewall dielectric layer 120 is non-conducting and may be a single layer, one of silicon nitride, silicon oxynitride or silicon dioxide, or the deep trench liner may consist of multiple layers of silicon nitride, silicon oxynitride and silicon dioxide. The deep trench sidewall dielectric layer 120 is discontinuous at the bottom of the deep trench 116. An electrically conductive deep trench-fill material 122 is on the surface of the deep trench sidewall dielectric layer 120 and forms a conductive core for the integrated deep trench 114. The electrically conductive deep trench-fill material 122 includes primarily silicon, and may be implemented as polycrystalline silicon, commonly referred to as polysilicon. Alternatively, the electrically conductive deep trench-fill material 122 may be implemented as amorphous silicon, or semi-amorphous silicon. The electrically conductive deep trench-fill material 122 provides an electrically conductive path between the wafer surface and the base wafer 110 through the deep trench to base wafer opening 124. The electrically conductive deep trench-fill material 122 may have the second conductivity type, p-type in this example. The electrically conductive deep trench-fill material 122 may have an average concentration of dopants of 5×10¹⁸ cm⁻³ and 1×10²⁰ cm⁻³, to provide a low equivalent series resistance for the integrated deep trench 114. The electrically conductive deep trench-fill material 122, may have an integrated deep trench doped region 132 near the top surface 118 to provide low resistivity between the electrically conductive deep trench-fill material 122 and contacts 144 to the interconnects 146. Another method of providing isolation between the diode and other components of the microelectronic device is through the use of an isolation implant of the second conductivity type and a buried layer of the second conductivity type around the diode. Other methods of isolating the diode 102 from other circuit elements of the microelectronic device 100 are within the scope of this disclosure.

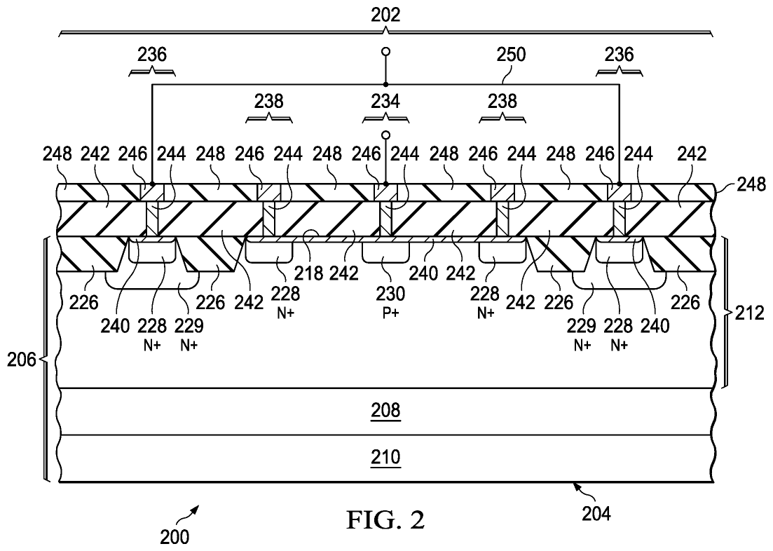

A field oxide 126 may be used to prevent silicide formation between subsequently formed anode 136, cathode 134, and guard structure 138 elements of the diode 102. In the example shown in FIG. 1, the field oxide 126 is local oxidation of silicon (LOCOS), but the field oxide 126 may be shallow trench isolation as shown in FIG. 2. A silicide block layer (not specifically shown) or polysilicon with dielectric sidewalls (not specifically shown) may also be used instead of a field oxide 126 to prevent silicide formation between the cathode 134, anode 136, and the guard structure 138. The dielectric sidewalls of the polysilicon may be one of silicon dioxide, silicon oxynitride, and silicon nitride.

The cathode 134 of the diode 102 consists of a doped region of the first conductivity type 128. In this example, the first conductivity type is n-type and may consist of arsenic or phosphorus. The phosphorus and arsenic may be implanted at a total dose of 1×10¹⁵ ions/cm² to 1×10¹⁶ ions/cm², and may be implanted with an energy of 20 keV to 80 keV by way of example.

In FIG. 1, the anode 136 and the guard structure 138 consists of a doped region of the second conductivity type 130. In this example, the second conductivity type 130 is p-type and may consist of boron. The boron may be implanted at a total dose of 1×10¹⁵ ions/cm² to 1×10¹⁶ ions/cm², and may be implanted with an energy of 10 keV to 50 keV by way of example.

The integrated deep trench 114 may have an integrated deep trench doped region 132 of the same conductivity type (p-type in this example) as the electrically conductive deep trench-fill material 122 to improve contact resistance. The doping may be of boron. The boron may be implanted at a total dose of 1×10¹⁵ ions/cm² to 1×10¹⁶ ions/cm², and may be implanted with an energy of 10 keV to 50 keV by way of example

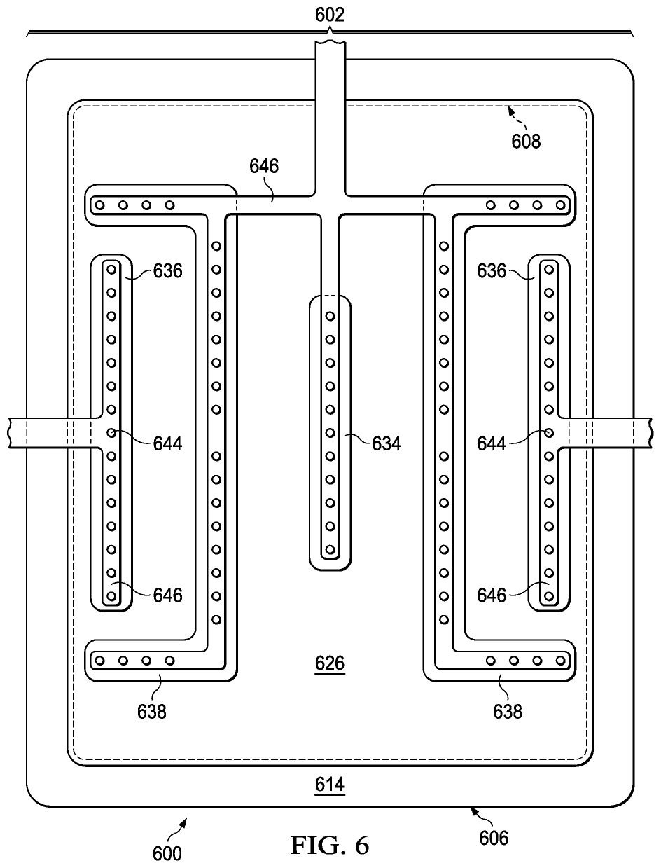

A metal silicide 140 may provide low resistance between contacts 144 and the doped region of the cathode 134, anode 136 and guard structure 138. A pre metal dielectric (PMD) 142 is on the top surface 118 of the silicon 106. Contacts 144 provide a conductive pathway between the elements in the silicon 106 of the diode 102 and the interconnects 146. An anode connection 150 above the top surface may be used to connect anode 136 elements of the diode 102 if the diode 102 consists of more than one anode 136 element in the silicon as shown in FIG. 1 and FIG. 6. A cathode 134 to guard structure connection 152 of a conductive material is used to connect the guard structure 138 to the cathode 134. The cathode to guard structure connection 152 may have an optional switching element 154 which allows the guard structure 138 and the cathode 134 to be electrically isolated above the top surface 118 of the silicon 106. The cathode to guard structure connection 152 may be made using interconnects 146, or may be made using on the top surface 118 of the silicon 106 by removal of field oxide 126 between the cathode 134 and the guard structure 138.

FIG. 2 shows cross sectional view of a microelectronic device 200 including a diode 202. The microelectronic device 200 may be manifested as a discrete semiconductor device, an integrated circuit, a micro-electrical mechanical system (MEMS) device, an electro-optical device, or a microfluidic device, by way of example. The substrate 204 may be, for example, part of a bulk semiconductor wafer, part of a semiconductor wafer with an epitaxial layer 212, part of a silicon-on-insulator (SOI) wafer, or other structure suitable for forming the microelectronic device 200.

The substrate 204 may include a n-type buried layer (NBL) 108 on a base wafer 210. The base wafer 210 may be p-type with a dopant concentration of 1×10¹⁷ atoms/cm³ to 1×10¹⁸ atoms/cm³, for example. Alternatively, the base wafer 210 may be lightly doped, with an average dopant concentration below 1×10¹⁶. The NBL 208 may be 2 microns to 10 microns thick, by way of example, and may have a dopant concentration of 1×10¹⁶ atoms/cm³ to 1×10¹⁷ atoms/cm³. The substrate 204 may include an epitaxial layer 212 of silicon on the NBL 208. The epitaxial layer 212 is part of the silicon 106, and may be 2 microns to 12 microns thick, for example. The epitaxial layer 212 may be p-type in this example, with a dopant concentration of 1×10¹⁵ atoms/cm³ to 1×10¹⁶ atoms/cm³, by way of example.

A field oxide 226 may be used to prevent silicide formation between subsequently formed cathode 236, and guard structure 238 elements of the diode 202. In the example shown in FIG. 2, the field oxide 226 is shallow trench isolation (STI), but the field oxide 126 may be LOCOS isolation in some embodiments. A silicide block layer (not specifically shown) or polysilicon with dielectric sidewalls (not specifically shown) may also be used instead of a field oxide 226 to prevent silicide formation between the cathode 236, and the guard structure 238. The dielectric sidewalls of the polysilicon may be one of silicon dioxide, silicon oxynitride, and silicon nitride.

In FIG. 2, the cathode 236 of the diode 202 consists of a doped region of the first conductivity type 228. In this example, the doped region of the first conductivity type 228 is n-type and may consist of arsenic or phosphorus. The phosphorus and arsenic may be implanted at a total dose of 1×10¹⁵ ions/cm² to 1×10¹⁶ ions/cm², and may be implanted with an energy of 20 keV to 80 keV by way of example. Optionally, a doped well region 229 may be used in addition to the doped region of the first conductivity type 228. The doped well region 229 is of the first conductivity type and may be of phosphorous or arsenic. In one example of the doped well region 229, arsenic may be implanted with a dose of about 5.0×10¹³ cm⁻²-5.0×10¹⁵ cm⁻² and implanted with an energy of 20 keV to 80 keV by way of example.

In FIG. 2, the anode 234 consists of a doped region of the second conductivity type 230. In this example, the second conductivity type 230 is p-type and may consist of boron. The boron may be implanted at a total dose of 1×10¹⁵ ions/cm² to 1×10¹⁶ ions/cm², and may be implanted with an energy of 10 keV to 50 keV by way of example. The guard structure 238 consists of a doped region of the first conductivity type 228 is n-type and may consist of arsenic or phosphorus. The phosphorus and arsenic may be implanted at a total dose of 1×10¹⁵ ions/cm² to 1×10¹⁶ ions/cm², and may be implanted with an energy of 20 keV to 80 keV by way of example.

A metal silicide 240 may provide low resistance between contacts 244 and the doped region of the cathode 236, the anode 234 and the guard structure 238. In FIG. 2, the metal silicide 240 provides a conductive connection between the anode 234 and the guard structure 238. A pre metal dielectric (PMD) 242 is on the top surface 218 of the silicon 206. Contacts 244 provide a conductive pathway between the elements in the silicon 206 of the diode 202 and the interconnects 246. A cathode connection 250 above the top surface may be used to connect cathode 236 elements of the diode 202 if the diode 202 consists of more than one cathode 236 element in the silicon as shown in FIG. 2.

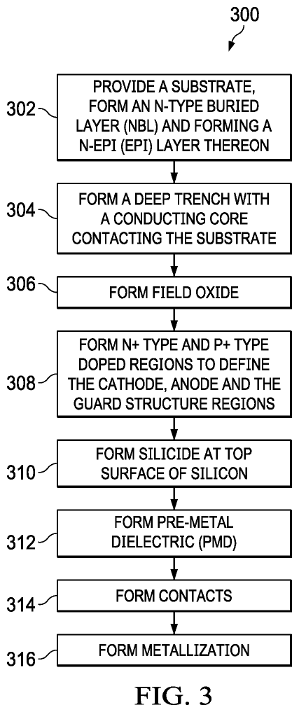

FIG. 3 presents a flowchart of an example method 300 of forming the microelectronic device 100 of FIG. 1. Structural elements referred to in the steps of the method 300 are shown in FIG. 1. The method 300 includes step 302, which may include forming the NBL 108 on the base wafer 110. The NBL 108 may be formed by forming a hard mask, not explicitly shown, over the base wafer 110 that exposes the base wafer 110 in an area for the NBL 108. n-type dopants, such as antimony and optionally some arsenic, are implanted into the base wafer 110 at a dose of 5×10¹⁴ ions/cm² to 3×10¹⁵ ions/cm², where exposed by the hard mask. The substrate 104 is heated to diffuse and activate the implanted n-type dopants to form the NBL 108.

Step 302 includes forming the epitaxial layer 112 (lightly n-type doped) on the NBL 108. The epitaxial layer 112 may be formed by an epitaxial process after the NBL 108 is formed. The n-type dopants of the NBL 108 may diffuse into the epitaxial layer 112 during the epitaxial process.

The method 300 continues with step 304 which includes forming an integrated deep trench 114 which provides both isolation between the diode 102 and other components of the microelectronic device 100 and a substrate contact to the underlying base wafer 110.

The formation of the integrated deep trench 114 may begin with the formation of a pad oxide layer, nitride cap layer, and oxide hard mask (none specifically shown) on the top surface 118 of the silicon 106. After the formation of the pad oxide layer, nitride cap layer, oxide hard mask layer, a pattern and etch step form the deep trench 116. in the silicon 106. A deep trench sidewall dielectric layer 120 is formed in the deep trench 116, contacting the silicon 106. The deep trench sidewall dielectric layer 120 may include a single layer of a silicon-nitrogen compound or a silicon dioxide compound or may include multiple layers of silicon-nitrogen compounds, silicon dioxide compounds, or other dielectric materials.

After the deposition of the deep trench sidewall dielectric layer 120, a trench dielectric etch process (not specifically shown) may be performed to improve thickness uniformity of deep trench sidewall dielectric layer 120 along sidewalls of the deep trench 116 and the trench dielectric etch may also be used to form a deep trench to base wafer opening 124 in the deep trench sidewall dielectric layer 120 to provide a conductive pathway between the subsequently formed electrically conductive deep trench-fill material 122 and the base wafer 110.

After the formation of the deep trench sidewall dielectric layer 120, an electrically conductive deep trench-fill material 122 is formed in the deep trench 116 on the deep trench sidewall dielectric layer 120. The electrically conductive deep trench-fill material 122 includes primarily silicon, and may be implemented as polycrystalline silicon, commonly referred to as polysilicon. Alternatively, the electrically conductive deep trench-fill material 122 may be implemented as amorphous silicon, or semi-amorphous silicon. The electrically conductive deep trench-fill material 122 may have an average concentration of dopants of 5×10¹⁸ cm⁻³ and 1×10²⁰ cm⁻³, to provide a low equivalent series resistance for the integrated deep trench 114. The doping is p-type in FIG. 1. After the deposition of the electrically conductive deep trench-fill material 122 and the deep trench sidewall dielectric layer 120 a chemical mechanical polish process or an etch back process (not specifically shown) may be used to remove the electrically conductive deep trench-fill material 122 and the deep trench sidewall dielectric layer 120 on the top surface 118 of the silicon 106.

The method 300 continues with step 304 which includes forming a field oxide 126. A pad oxide (not specifically shown) of silicon dioxide e.g. (10 nm-20 nm) may be formed of the top surface 118 of the silicon 106. After the deposition of the pad oxide, a layer of silicon nitride (not specifically shown) may be formed with a thickness of 100 nm to 200 nm. A layer of photoresist (not specifically shown) is formed and patterned to define areas where the silicon nitride is to be removed to exposed the top surface 118. A silicon nitride etch process may be used to remove silicon nitride in the exposed areas to define regions for the field oxide 126. After removal of the photoresist, a LOCOS process may be used to grow field oxide 126 on areas of the top surface 118 where the silicon nitride has been removed. The LOCOS process may be a thermal steam oxidation at a temperature above 950 C.

The method 300 continues with step 308 which in includes photolithography and implant steps to form the cathode 134, anode 136, and guard structure 138. A doped region of the first conductivity type 128 (n-type in this example) is implanted to define the cathode 134, and a doped region of the second conductivity type 130 (p-type in this example) is implanted to define the anode 136 and the guard structure 138. Additionally, during this series of photolithography and implant steps, an integrated deep trench doped region 132 of the same conductivity type as the electrically conductive deep trench-fill material 122 may be formed. In this example, the electrically conductive deep trench-fill material 122 is p-type, so a p-type dopant is used.

For the n-type implant, n-type dopants, such as phosphorus and arsenic, are implanted into the top surface 118 where exposed by the implant mask (not specifically shown). The phosphorus and arsenic may be implanted at a total dose of 1×10¹⁵ ions/cm² to 1×10¹⁶ ions/cm², and may be implanted with an energy of 20 keV to 80 keV by way of example. After the phosphorus and arsenic are implanted, the substrate 104 is heated, for example by a rapid thermal process (RTP) tool, to activate the implanted phosphorus and arsenic to form the doped region of the first conductivity type 128 of the diode 102.

For the p-type implant, p-type dopants, such as boron are implanted into the top surface 118 where exposed by a second implant mask (not specifically shown). The boron may be implanted at a total dose of 1×10¹⁵ ions/cm² to 1×10¹⁶ ions/cm², and may be implanted with an energy of 10 keV to 50 keV by way of example. After the boron implanted, the substrate 104 is heated, for example by a rapid thermal process (RTP) tool, to activate the implanted boron in the doped region of the second conductivity type 130, and the integrated deep trench doped region 132 for the diode 102. Other methods of forming the doped region of the first conductivity type 128, the doped region of the second conductivity type 130 and the integrated deep trench doped region 132 are within the scope of this disclosure.

The method 300 continues with step 310 shown in FIG. 3 which includes forming the metal silicide 140. The metal silicide 140 may be formed by forming a layer of metal on the microelectronic device 100 at the top surface 118, contacting the silicon 106. The layer of metal may include platinum, tungsten, titanium, cobalt, nickel, chromium, or molybdenum, by way of example. A cap layer of titanium nitride or tantalum nitride may be formed over the layer of metal. Subsequently, the microelectronic device 100 is heated to react the layer of metal with the silicon 106, and the polysilicon, to form the metal silicide 140. Unreacted metal in regions such as over the field oxide 126 is removed from the microelectronic device 100, leaving the metal silicide 140 in place. The unreacted metal may be removed by a wet etch process using an aqueous mixture of sulfuric acid and hydrogen peroxide, or an aqueous mixture of nitric acid and hydrochloric acid, by way of example. The metal silicide 140 may provide lower resistance for contacts 144 to the cathode 134, the anode 136, the guard structure 138, and the integrated deep trench 114 with lower resistances compared to a similar microelectronic device 100 without metal silicide 140. The metal silicide 140/240 may be used as a conductive connection between the cathode 134/234 (first terminal in this example) and the guard structure 138/238 as shown in FIG. 2. Other methods of forming the metal silicide 140 are within the scope of this disclosure.

The method 300 continues with step 312, which includes forming a pre metal dielectric (PMD) layer 142. The PMD layer 142 may include a PMD liner (not specifically shown) over the microelectronic device 100 which may be formed from one of silicon nitride, silicon oxynitride and silicon dioxide. The PMD layer 142 is formed over the PMD liner if present. The PMD layer 142 may be formed by one or more dielectric deposition processes, including a PECVD process using TEOS, a high density plasma (HDP) process, or a high aspect ratio process (HARP) using TEOS and ozone, by way of example. The PMD layer 142 may be planarized by an oxide CMP process. Other methods of forming the PMD layer 142 are within the scope of this disclosure.

The method 300 continues with step 314, which includes forming the contacts 144 through the PMD layer 142 and the PMD liner if present. The contacts 144 may be formed by etching holes through the PMD layer 142 and the PMD liner if present to expose the metal silicide 140, In one version of step 314, the contacts 144 may be formed by sputtering titanium to form a titanium adhesion layer, followed by forming the titanium nitride diffusion barrier using reactive sputtering or an ALD process. The tungsten core may be formed by an MOCVD process using tungsten hexafluoride (WF₆) reduced by silane initially and hydrogen after a layer of tungsten is formed on the titanium nitride diffusion barrier. The tungsten, titanium nitride, and titanium is subsequently removed from a top surface of the PMD layer 142 by an etch process, a tungsten CMP process, or a combination of both, leaving the contacts 144 extending to the top surface of the PMD layer 142. In another version of step 314, the contacts 144 may be formed by a selective tungsten deposition process which fills the contacts 144 with tungsten from the bottom up, forming the contacts 144 with a uniform composition of tungsten. Other methods of forming the contacts 144 are within the scope of this disclosure. The method 300 continues with step 316, which includes forming the interconnects 146 on the contacts 144. The interconnects 146 may be used as a conductive connection between the cathode 134 (first terminal in this example) and the guard structure 138 as shown in FIG. 1.

In versions of this example in which the interconnects 146 have an etched aluminum structure, the interconnects 146 may be formed by depositing an adhesion layer, an aluminum layer, and an anti-reflection layer, and forming an etch mask, not explicitly shown, followed by an RIE process to etch the anti-reflection layer, the aluminum layer, and the adhesion layer where exposed by the etch mask, and subsequently removing the etch mask.

In versions of this example in which the interconnects 146 have a damascene structure, the interconnects 146 may be formed by forming the IMD layer 148 on the PMD layer 142, and etching the interconnect trenches through the IMD layer 148 to expose the contacts 144. The barrier liner may be formed by sputtering tantalum onto the IMD layer 148 and the PMD layer 142 which is exposed and contacts 144, and forming tantalum nitride on the sputtered tantalum by an ALD process. The copper fill metal may be formed by sputtering a seed layer, not explicitly shown, of copper on the barrier liner, and electroplating copper on the seed layer to fill the interconnect trenches. Copper and barrier liner metal is subsequently removed from a top surface of the IMD layer 148 by a copper CMP process.

In versions of this example in which the interconnects 146 have a plated structure, the interconnects 146 may be formed by sputtering the adhesion layer, containing titanium, on the PMD layer 142 and contacts 144, followed by sputtering a seed layer, not explicitly shown, of copper on the adhesion layer. A plating mask is formed on the seed layer that exposes areas for the interconnects 146. The interconnects 146 are formed by electroplating copper on the seed layer where exposed by the plating mask. The plating mask is removed, and the seed layer and the adhesion layer are removed by wet etching between the interconnects 146.

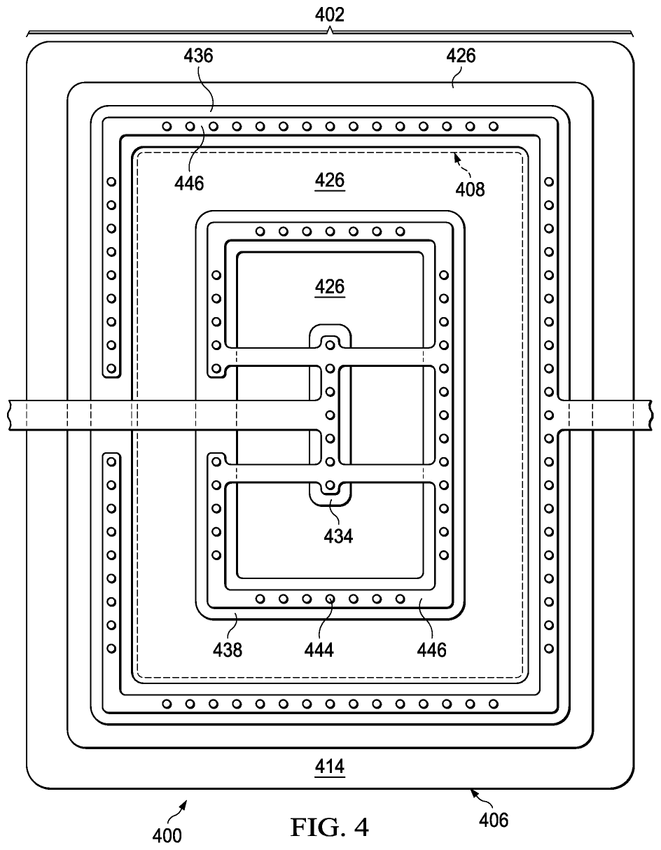

FIG. 4 shows top down view of a microelectronic device 400 including an integrated guard structure diode 402 using the method of FIG. 3. The structure is on the silicon 406. The cathode 434 may be configured as a bar at the center of the integrated guard structure diode 402. The guard structure 438 in FIG. 4 may be a ring of guard structure 438 which surrounds the cathode 434. The anode 436 may be configured as a ring around the guard structure 438, such that the guard structure 438 is between the anode 436 and the cathode 434. The cathode 434, anode 436 and guard structure 438 are over a field of NBL 408 which is surrounded by a ring of integrated deep trench 414. Field oxide 426 prevents silicide formation (as discussed in step 310 of FIG. 3) and provides electrical isolation of the cathode 434, anode, 436, guard structure 438, and integrated deep trench 414 at the surface of the silicon 406. Other silicide blocking methods such as a silicide block layer (not specifically shown) or polysilicon with sidewalls (not specifically shown) or other methods may be used to prevent formation of metal silicide 140 as discussed in FIG. 1. Contacts 444 make conductive connections between the cathode 434, anode 436, and the guard structure 438 and the interconnects 446. In FIG. 4, the cathode 434, and the guard structure 438 are connected through the interconnects 446. An optional switching element 154 as shown in FIG. 1 may be used to selectively separate the cathode 434 from the guard structure 438. The connection between the guard structure 438 and the cathode 434 may be through the silicide (not specifically shown) if field oxide 426 is not present between the guard structure 438 and the cathode 434 during the formation of the silicide (not specifically shown).

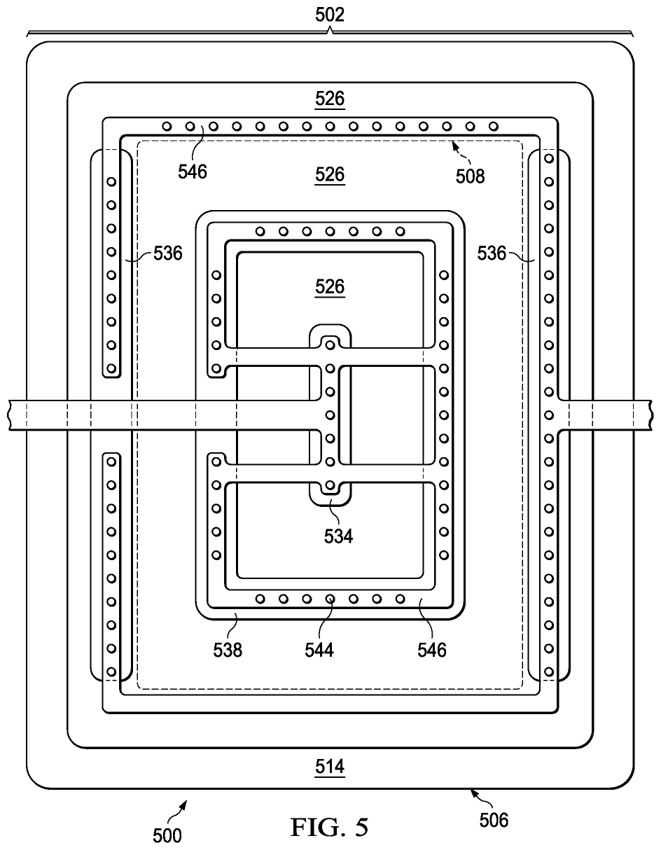

FIG. 5 shows top down view of a microelectronic device 500 including an integrated guard structure diode 502. The structure is on the silicon 506. In FIG. 5, the anode 536 (second terminal in this example) is discontinuous around the guard structure 538. In FIG. 5, the cathode 534 may be configured as a bar at the center of the integrated guard structure diode 502. The guard structure 538 in FIG. 5 may be a ring of guard structure 538 which surrounds the cathode 534. The anode 536 may be configured as bars of anode 536 around the guard structure 538, such that the guard structure 538 is between the anode 536 and the cathode 534. While two bars of anode 536 are shown in FIG. 5, other configurations of anode 536 bars such that the guard structure 538 is between the anode 536 and the cathode 534 are within the scope of this disclosure. The cathode 534, anode 536 and guard structure 538 are over a field of NBL 508 which is surrounded by a ring of integrated deep trench 514. Field oxide 526 prevents silicide formation (as discussed in step 310 of FIG. 3) and provides electrical isolation of the cathode 534, anode, 536, guard structure 538, and integrated deep trench 514 at the surface of the silicon 506. Other silicide blocking methods such as a silicide block layer (not specifically shown) or polysilicon with sidewalls (not specifically shown or other methods may be used to prevent silicide formation between the cathode 534, anode, 536, guard structure 538, and integrated deep trench 514 at the surface of the silicon 506 and are within the scope of this disclosure. Contacts 544 make conductive connections between the cathode 534, anode 536, and the guard structure 538 and the interconnects 546. In FIG. 4, the cathode 534, and the guard structure 538 are connected through the interconnects 546. An optional switching element 154 as shown in FIG. 1 may be used to selectively separate the cathode 534 from the guard structure 538. The connection between the guard structure 538 and the cathode 534 may be through the silicide (not specifically shown) if field oxide 526 is not present between the guard structure 538 and the cathode 534 during the silicide formation (not specifically shown).

FIG. 6 shows top down view of a microelectronic device 600 including an integrated guard structure diode 602. The structure is on the silicon 606. In FIG. 6, the cathode 634 may be configured as a bar at the center of the integrated guard structure diode 602. The guard structure 638 in FIG. 5 may consist of one or more guard structures 638 in a parentheses shape which do not allow a direct path between the cathode 634 and the anode 636. While the guard structure 638 is a parentheses shape in FIG. 6, other shapes of guard structure 638 are within the scope of this disclosure. In FIG. 6 the anode 636 may be configured as bars of anode 636 such that the guard structure 638 is between the anode 636 and the cathode 634. While two bars of anode 636 are shown in FIG. 6, other configurations of anode 636 bars such that the guard structure 638 is between the anode 636 and the cathode 634 are within the scope of this disclosure. The cathode 634, anode 636 and guard structure 638 are over a field of NBL 608 which is surrounded by a ring of integrated deep trench 614. Field oxide 626 prevents silicide formation (as discussed in step 310 of FIG. 3) and provides electrical isolation of the cathode 634, anode, 636, guard structure 638, and integrated deep trench 614 at the surface of the silicon 606. Other silicide blocking methods such as a silicide block layer (not specifically shown) or polysilicon with dielectric sidewalls (not specifically shown or other methods may be used to prevent silicide formation between the cathode 634, anode 636, guard structure 638, and integrated deep trench 614 at the surface of the silicon 606 and are within the scope of this disclosure. Contacts 644 make conductive connections between the cathode 634, anode 636, and the guard structure 638 and the interconnects 646. In FIG. 6, the cathode 634, and the guard structure 638 are connected through the interconnects 646. An optional switching element 154 as shown in FIG. 1 may be used to selectively separate the cathode 634 from the guard structure 638. The connection between the guard structure 638 and the cathode 634 may be through the silicide (not specifically shown) if field oxide 626 is not present between the guard structure 638 and the cathode 634 during silicide formation (not specifically shown).

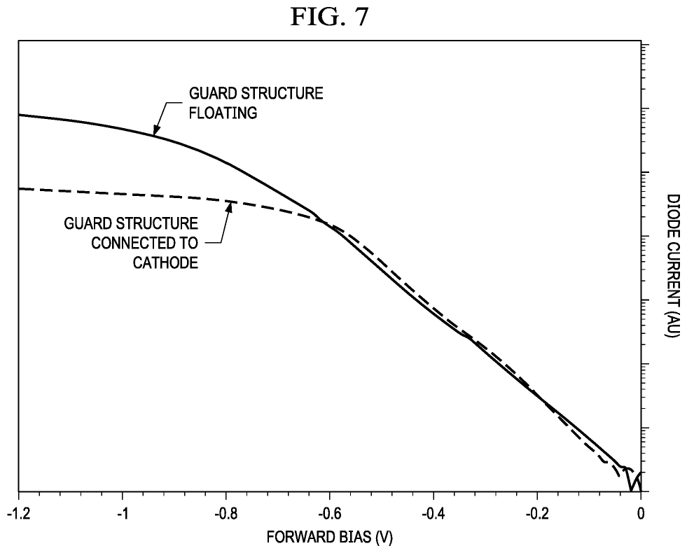

FIG. 7 shows a graph comparing a diode current versus a forward bias voltage for a diode with a guard structure and a diode without a guard structure. The diode current at increased forward bias voltage is higher for the diode without the guard structure than for the diode with the guard structure. This is due to the guard structure of the diode draining minority carriers and minimizing conductivity modulation which results in lower diode current at higher forward bias for a diode with a guard structure compared to a diode without a guard structure.

While various embodiments of the present disclosure have been described above, it should be understood that they have been presented by way of example only and not limitation. Numerous changes to the disclosed embodiments can be made in accordance with the disclosure herein without departing from the spirit or scope of the disclosure. Thus, the breadth and scope of the present invention should not be limited by any of the above described embodiments. Rather, the scope of the disclosure should be defined in accordance with the following claims and their equivalents.

What is claimed is:

1. A microelectronic device including a diode, comprising:
a substrate;
a semiconductor material of a first conductivity type on the substrate;
a first terminal of the diode, the first terminal having the first conductivity type, in the semiconductor material;
a second terminal of the diode, the second terminal having a second conductivity type, in the semiconductor material;
a guard structure of the diode, the guard structure having the second conductivity type, in the semiconductor material, wherein the guard structure is laterally separated from the second terminal, and the guard structure is between the first terminal and the second terminal; and
a conductive connection between the first terminal of the diode and the guard structure.

2. The microelectronic device of claim 1, wherein the first conductivity type is n-type and the second conductivity type is p-type, and the first terminal is a cathode and the second terminal is an anode.

3. The microelectronic device of claim 1, wherein the first conductivity type is p-type and the second conductivity type is n-type, and the first terminal is an anode and the second terminal is a cathode.

4. The microelectronic device of claim 1, wherein the microelectronic device includes a silicide blocking layer over the substrate between the guard structure and the second terminal.

5. The microelectronic device of claim 4, wherein the silicide blocking layer includes a material selected from the group consisting of silicon dioxide, silicon nitride, and silicon oxynitride.

6. The microelectronic device of claim 4, wherein the silicide blocking layer includes polysilicon having a dielectric sidewall.

7. The microelectronic device of claim 1 wherein a silicide is used as a conductive connection between the first terminal and the guard structure.

8. The microelectronic device of claim 1 wherein an interconnect is used as the conductive connection between the first terminal and the guard structure.

9. The microelectronic device of claim 1, wherein there is a switching element in the conductive connection between the first terminal and the guard structure.

10. The microelectronic device of claim 1, wherein a deep trench contacting the substrate separates the diode from other elements of the microelectronic device.

11. The microelectronic device of claim 1, wherein a doped region of the second conductivity type separates the diode from other elements of the microelectronic device.

12. The microelectronic device of claim 1, wherein the guard structure surrounds the first terminal.

13. The microelectronic device of claim 1, wherein the second terminal surrounds the guard structure.

14. The microelectronic device of claim 1, wherein the second terminal is discontinuous around the guard structure.

15. The microelectronic device of claim 1, wherein the guard structure is discontinuous with no direct path between the second terminal and the first terminal.

16. A method of forming a microelectronic device including a diode, comprising:
forming a first terminal of the diode having a first conductivity type in a semiconductor material on a substrate, the semiconductor material having the first conductivity type;
forming a second terminal of the diode having a second conductivity type in the semiconductor material;
forming a guard structure having the second conductivity type in the semiconductor material, wherein the guard structure is laterally separated from the second terminal, and the guard structure is between the first terminal and the second terminal; and
forming a conductive connection between the first terminal and the guard structure.

17. The method of claim 16, wherein the first conductivity type is n-type and the second conductivity type is p-type, and the first terminal is a cathode and the second terminal is an anode.

18. The method of claim 16, wherein the first conductivity type is p-type and the second conductivity type is n-type, and the first terminal is an anode and the second terminal is a cathode.

19. The method of claim 16, wherein the microelectronic device includes a silicide blocking layer over the substrate between the guard structure and the second terminal.

20. The method of claim 16 wherein a silicide is used as a conductive connection between the first terminal and the guard structure.

21. The method of claim 16 wherein an interconnect is used as the conductive connection between the first terminal and the guard structure.

22. The method of claim 19, wherein the silicide blocking layer includes poly silicon having a dielectric sidewall.

23. The method of claim 16, wherein there is a switching element in the conductive connection between the first terminal and the guard structure.

24. The method of claim 16, wherein a deep trench contacting the substrate separates the diode from other elements of the microelectronic device.

25. The method of claim 16, wherein a doped region with the second conductivity type separates the diode from other elements of the microelectronic device.
